(19) United States
(12) Patent Application Publication
(10) Pub. No.: US 2005/0106888 A1
(43) Pub. Date: May 19, 2005

(54) Method of in-situ damage removal - post O2 dry process

(75) Inventors: Yuan-Hung Chiu, Taipei (TW); Ming-Ching Chang, Hsin-Chu (TW); Hun-Jan Tao, Hsinchu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Co.

(21) Appl. No.: 10/714,207

(22) Filed: Nov. 14, 2003

(51) Int. Cl. H01L 21/302; H01L 21/461

(52) U.S. Cl. 438/710; 438/725; 438/723

(57) ABSTRACT

An integrated process flow including a plasma step for removing oxide residues following oxygen ashing of a photoresist layer is disclosed. The oxide removal step is effective in preventing micro mask defects and is preferably performed in the same process chamber used for the oxygen ashing step and for a subsequent plasma etch used for pattern transfer. The oxide removal step takes less than 60 seconds and involves a halogen containing plasma that is generated from one or more of NF₃, Cl₂, CF₄, CH₂F₂, and SF₆. Optionally, HBr or a fluorocarbon C_{X}F_{Y}H_{Z} where x and y are integers and z is an integer or is equal to 0 may be used alone or with one of the aforementioned halogen containing gases. The oxide removal step may be incorporated in a variety of applications including a damascene scheme, shallow trench (STI) fabrication, or formation of a gate electrode in a transistor.

### FIELD OF THE INVENTION

The invention relates to the field of integrated circuit fabrication and in particular to a method of removing oxide residues from a substrate after an oxygen plasma step and before subsequent processing that may include etching an exposed portion of a substrate or removing an underlayer.

### BACKGROUND OF THE INVENTION

Two of the more important processes that are repeated numerous times during the fabrication of a semiconductor device are photoresist patterning and plasma etching which transfer a pattern from a mask into a photoresist layer and then into one or more underlying layers. The patterned photoresist layer serves as a mask while openings such as vias and trenches in the photoresist layer provide a pathway for reactive ions to remove an exposed underlying layer, or in some cases, more than one underlying layer in an integrated process flow.

A photoresist layer is not thermally stable at temperatures above approximately 150° C. and therefore must be removed after the pattern transfer is complete. Generally, the remaining photoresist layer is stripped by an oxygen ashing method to avoid the cost and contamination concerns associated with a wet organic stripper. An ashing method also enables an integrated etch sequence in which several etch steps including the photoresist strip are performed in the same etch chamber or within the same multi-chambered etch tool to increase throughput. Although a typical photoresist containing the elements of C, H, N, S and O is converted to volatile oxides, the reactive oxygen species during the oxygen ashing step come in contact with silicon containing layers such as interlevel dielectric (ILD) layers, intermetal dielectric (IMD) layers, polysilicon gates, and silicon substrates. As a result, non-volatile SiO₂ residues are formed and deposited within etched openings and on the substrate. These non-volatile residues are referred to as micromasks since they are able to block a subsequent plasma etch from entirely removing an underlying layer.

In FIG. 1, an example of a patterned photoresist layer that serves as a mask for transferring an opening into a substrate is shown. A pad oxide layer 2 and a silicon nitride layer 3 are sequentially deposited on a substrate 1. A photoresist layer 4 is coated on the silicon nitride layer 3 and is patterned to form openings 5, 6, 7. The openings 5, 6, 7 are transferred through the silicon nitride layer 3 and optionally through the pad oxide layer 2 by a fluorocarbon based etch such as CHF₃, for example.

Referring to FIG. 2, the photoresist layer 4 is removed by an oxygen ashing step. However, some oxide residues 8 are formed within the openings 5, 6, 7 and on the silicon nitride layer 3. Although a conventional buffered HF treatment could be used to remove the oxide residues 8, this method is not recommended since the wet etchant may attack the substrate 1 below pad oxide regions 2 to form grooves (not shown) that degrade device performance.

Referring to FIG. 3, if the oxide residues 8 are not removed and a silicon substrate 1 is etched to form shallow trench isolation (STI) features 9a, 9b, 9c, the oxide residues 8 act as micromasks to block the removal of underlying silicon. As a result, tall columns of silicon 1a which are considered defects remain in the shallow trench regions 8. An expensive rework process is necessary to remove the defects 1a. Therefore, an improved method is needed that avoids micro mask defects 1a by removing the oxide residues 8 prior to forming the STI regions 9a, 9b, 9c.

As mentioned previously, the oxide residue problem is not unique to STI formation but is also a concern following an O₂ ashing of a photoresist layer that is used to pattern an ILD or IMD layer during the formation of a metal interconnect. In addition, oxide residues are usually produced by an O₂ ashing of a photoresist layer which is used to pattern a gate electrode during fabrication of a transistor. Therefore, a desirable method of removing oxide residue is versatile in that it is equally effective in a variety of applications.

A method for reducing plasma induced damage to a substrate is described in U.S. Pat. No. 6,521,302 in which a plasma power is gradually ramped down rather than stopping abruptly and completely. Additionally, gas flow rates are gradually decreased to dissipate surface charges.

In U.S. Pat. No. 6,407,004, a photoresist pattern is formed on two stacked conductive layers. A first etch with a halogen containing gas is used to etch through the top conductive layer and then an oxygen based etch is employed for pattern transfer through the bottom conductive layer. The bottom conductive layer is preferably Ru or RuO₂ which forms a gaseous RuO₄ that is evacuated through an exit port and thereby leaves no residue.

A dry process for removing an oxide residue in U.S. Pat. No. 5,228,950 involves a plasma etch including NF₃ and optionally a reactive gas or an inert gas in combination with an applied magnetic field of 25 to 150 Gauss. However, care must be taken not to overetch in order to avoid damage to polysilicon or gate oxide layers.

In U.S. Pat. No. 6,319,842, a method of cleaning vias is described in which non-volatile residues are first removed by sputtering with an inert gas plasma. A second step with a reducing gas plasma converts undesired oxide residues to metal and water. Unfortunately, sputtering can easily damage a substrate, especially the top corners of openings in a patterned layer so that critical dimension (CD) control is lost.

### SUMMARY OF THE INVENTION

One objective of the present invention is to provide an integrated method for removing oxide residues from a substrate in the same process chamber used for a preceding oxygen ashing step and for a subsequent pattern transfer step.

A further objective of the present invention is to provide a dry process for removing oxide residues from a substrate that prevents micro mask defects and does not damage exposed dielectric layers including ILD and IMD layers, and an etch stop layer.

A still further objective of the present invention is to provide a dry process for removing oxide residues from a substrate that is versatile and may be employed for a variety of applications including the fabrication of STI features, a gate electrode, and an interconnect in a microelectronics device.

These objectives are achieved in one embodiment by providing a substrate on which a photoresist has been patterned over a stack that includes an upper masking layer and a lower pad oxide layer. After the pattern is transferred through the masking layer and pad oxide layer, the photoresist layer is stripped by an oxygen ashing step that generates oxide residues on the masking layer and within the openings of the pattern. A short halogen containing plasma step is then performed in the same chamber in which the oxygen ashing was carried out to remove the oxide residues. Preferably, the halogen plasma comprises SF₆, NF₃, Cl₂, or a fluorocarbon gas C_{X}F_{Y}H_{Z} where x and y are integers and z is an integer or is 0 such as CF₄ and CH₂F₂. Following the halogen containing plasma step, a plasma etch in the same process chamber is used to form shallow trenches in the substrate with no micro mask defects.

In a second embodiment, a substrate is provided which has a patterned photoresist layer on a stack comprised of an upper hard mask layer, a middle polysilicon layer and a lower gate oxide layer. After the pattern is etched through the hard mask layer, the photoresist is stripped by an oxygen ashing step and oxide residues are formed on the hard mask and within the openings of the pattern. A short halogen containing plasma step is then performed in the same chamber in which the oxygen ashing was carried out to remove the oxide residues. Preferably, the halogen plasma comprises SF₆, NF₃, Cl₂, or a fluorocarbon gas C_{X}F_{Y}H_{Z} where x and y are integers and z is an integer or is 0. Following the halogen containing plasma step, a plasma etch in the same process chamber is used to transfer the pattern in the hard mask through the polysilicon layer to form a gate electrode.

In a third embodiment, a substrate is provided which has a patterned photoresist layer on a stack comprised of an upper dielectric layer and a lower etch stop layer. After the pattern is transferred through the dielectric layer, the photoresist is stripped by an oxygen ashing step and oxide residues are formed on the dielectric layer and within the openings of the pattern. A short halogen containing plasma step described in the first and second embodiments is then performed in the same chamber in which the oxygen ashing was carried out to remove the oxide residues and the exposed etch stop layer at the bottom of the opening. Following the halogen containing plasma step, an additional plasma step in the same process chamber is used to remove polymer residue formed during removal of the etch stop layer. Conventional processing is followed to complete the damascene scheme and form an interconnect in the opening.

### BRIEF DESCRIPTION OF THE DRAWINGS

FIGS. 1-2 are cross-sectional views depicting a process flow in which a photoresist layer is patterned on a substrate and an oxygen ashing step is used to strip the photoresist layer but produces oxide residues on the substrate.

FIG. 3 is a cross-sectional view showing the micro masking defects that result when the oxide residues in FIG. 2 are not removed before a pattern transfer to form shallow trenches is performed according to a prior art method.

FIG. 4 is a cross-sectional view that illustrates a halogen containing plasma step that removes oxide residues according to a first embodiment of this invention.

FIG. 5 is a cross-sectional view that illustrates removal of the oxide residues shown in FIG. 4 and formation of a shallow trench with no substrate damage according to the first embodiment of the present invention.

FIG. 6 is a cross-sectional view showing a patterned photoresist layer formed above an active region on a substrate and transfer of the pattern through a hard mask layer on a gate layer according to a second embodiment of the present invention.

FIG. 7 is a cross-sectional view of the structure in FIG. 6 after the photoresist layer is stripped and oxide residues are formed on the gate layer and on the hard mask.

FIG. 8 is a cross-sectional view that shows the removal of the oxide residues in FIG. 7 as a result of the halogen containing plasma step of the present invention.

FIG. 9 shows the transfer of the hard mask pattern in FIG. 8 through an underlying polysilicon layer with no micro mask defects according to the second embodiment.

FIGS. 10-13 show a sequence of steps that involve patterning a photoresist layer above a dielectric layer on a substrate, stripping the photoresist with an oxygen ashing step that forms oxide residues, removing the oxide residues and exposed etch stop layer with a halogen containing plasma step, and removing polymer residues with an additional plasma step according to a third embodiment of the present invention.

### DETAILED DESCRIPTION OF THE INVENTION

The present invention is a particularly useful method for removing oxide residues from a substrate, especially following an oxygen ashing step that strips an organic layer such as a photoresist or an organic anti-reflective coating (ARC). The drawings are provided by way of example and not as a limitation of the scope of the invention. Furthermore, the figures are not necessarily drawn to scale and the relative size of various elements may not be the same as in an actual microelectronics device.

The oxide residue removal method of the present invention is preferably integrated into a process flow in which a first step of oxygen ashing an organic layer, a second step of removing the oxide residues, and a third step involving a plasma etch for pattern transfer are performed in the same etch tool and more preferably in the same process chamber within an etch tool. The invention may be carried out in a split power etcher, a dual power etcher, a single power etcher, a reactive ion etch (RIE) tool, or in a conventional barrel, direct, or downstream type of ashing tool known to those who practice the art. Although the first and third steps may be considered conventional process steps, the optimum conditions employed for the key second step may vary somewhat depending upon the process conditions of the first and third steps and in particular, the composition of the adjacent layers in the device being fabricated.

Therefore, three embodiments of the present invention are provided although those skilled in the art will appreciate that other applications of the oxide residue removal method of this invention which are not discussed herein are possible. A first embodiment is depicted in FIGS. 1, 2, 4, and 5.

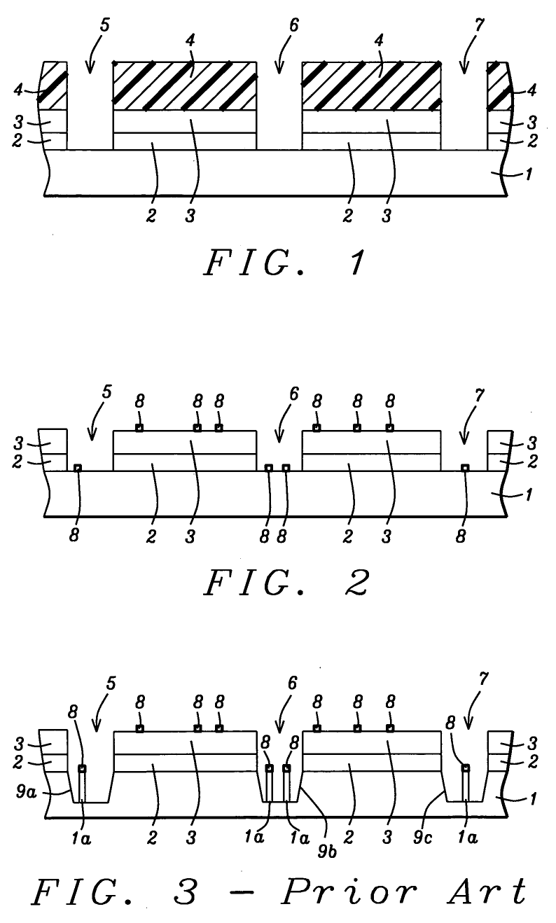

Although FIGS. 1 and 2 were described previously, a more detailed description is now provided of the various elements therein as they apply to the present invention. Referring to FIG. 1, a substrate 1 is shown that is typically silicon but may optionally be comprised of silicon-on-insulator (SOI), silicon-germanium (SiGe), gallium-arsenide (GaAs) or other semiconductor materials used in the art. The pad oxide layer 2 is grown on substrate 1 by a rapid thermal oxidation (RTO), for example, or may be deposited by a chemical vapor deposition (CVD) method. The pad oxide layer 2 has a thickness between about 30 and 300 Angstroms. A hard mask layer 3 comprised of silicon nitride or polysilicon and with a thickness of about 300 to 3000 Angstroms is deposited by a CVD or plasma enhanced CVD (PECVD) technique on the pad oxide layer 2. Next, a photoresist is coated on hard mask layer 3 to form a photoresist layer 4. Alternatively, an organic anti-reflective coating (ARC) which is not shown is coated on hard mask layer 3 prior to forming the photoresist layer 4. A conventional lithography method is followed to generate a pattern with openings 5, 6, and 7 in photoresist layer 4. The widths of the openings 5, 6, 7 may differ from one another and the width of the photoresist layer 4 between openings 5, 6 may be different than the width of the photoresist layer 4 between openings 6, 7. Additionally, other openings (not shown) may be present in the photoresist layer 4.

The openings 5, 6, 7 are transferred through hard mask layer 3 and through pad oxide layer 2 by conventional methods. In an alternative embodiment, a plasma etch comprised of HBr and O₂, for example, is used to transfer the openings 5, 6, 7 through the ARC layer before the hard mask layer 3 is etched. When the hard mask layer 3 is silicon nitride, a plasma etch comprising CHF₃ may be employed. For etching through a polysilicon hard mask, a plasma based on Cl₂ and HBr may be used, for example. Note that photoresist layer 4 is usually thinned by a plasma etch through hard mask layer 3.

Referring to FIG. 2, the substrate 1 is loaded into a process chamber of an etching tool and positioned on a chuck which holds the substrate in place. It is understood that the etching tool may have more than one process chamber and that a substrate may be transferred from one process chamber to another in an integrated process flow. The photoresist layer 4 is stripped by an oxygen ashing method. Alternatively, both the photoresist layer 4 and an organic ARC layer when present are removed by the O₂ ashing procedure. An example of O₂ ashing conditions are a chamber pressure of 10 mTorr, a RF power of 600 Watts, a bias power of 40 Watts, and a 200 standard cubic centimeter per minute (sccm) flow of O₂ for a 60 second period. The O₂ ashing procedure typically generates oxide residues 8 because the oxygen radicals in the oxygen ashing step come in contact with silicon containing layers and thereby form non-volatile SiO₂ residues. These oxide residues 8 are formed on the hard mask 3 and within the openings 5, 6, 7 and must be removed before further processing to form trenches in substrate 1 or micro masking defects 1a as pictured in FIG. 3 will occur.

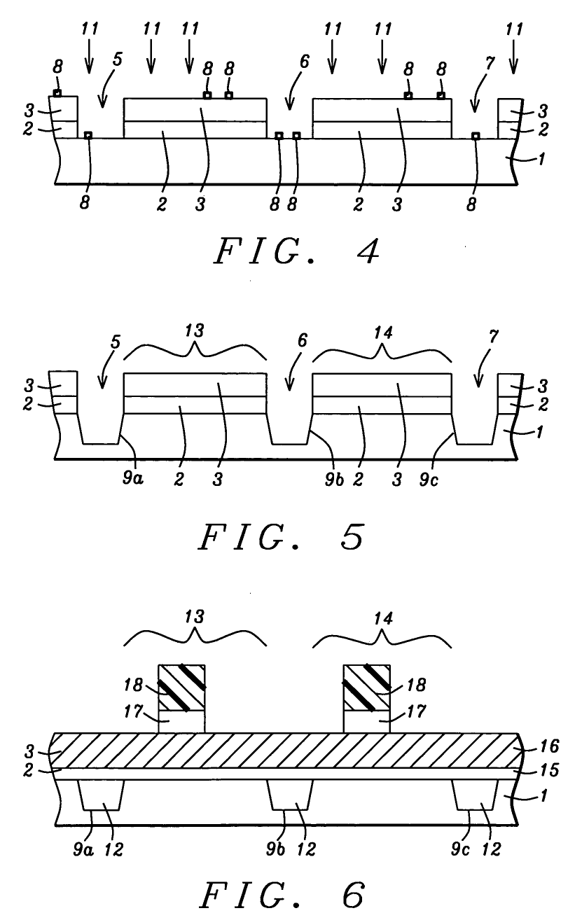

Referring to FIG. 4, a key feature of the present invention is a halogen containing plasma step 11 that effectively removes the oxide residues 8 pictured in FIG. 2 without damaging adjacent layers. The inventors have discovered that a plasma etch based on one or more of the halogen containing gases CF₄, CH₂F₂, SF₆, NF₃, and Cl₂ is especially effective in eliminating the oxide residues 8. Optionally, HBr or a fluorocarbon C_{X}F_{Y}H_{Z} where x and y are integers and z is an integer or is equal to 0 may be used alone or with one or more of the aforementioned halogen containing gases. For example, if excessive thinning of the hard mask 3 is a concern, then HBr may be used in combination with Cl₂ in plasma step 11 to avoid undesirable thickness loss in the hard mask layer. Preferably, the plasma step is carried out in the same etch tool that was used for the previous oxygen ashing step in order to enhance throughput. To decrease the amount of preventative maintenance needed to periodically clean the wall (not shown) of the O₂ ashing process chamber, the plasma step 11 is more preferably performed in the same process chamber that was used to strip the photoresist layer 4 since oxide residues can also accumulate on the process chamber wall.

The plasma step 11 is comprised of a halogen flow rate of about 3 to 500 sccm, a process chamber pressure of from 1 mTorr to 3 Torr, a process chamber temperature between about −15° C. and 150° C., a high frequency RF (HFRF) or top RF power of from 100 to 3000 Watts and a low frequency RF (LFRF) or bias power of about 10 to 1000 Watts for a period of less than 60 seconds and preferably for about 5 to 30 seconds. Optionally, an inert gas such as He, Ar, or N₂ may be flowed into the process chamber during the plasma step 11. In an alternative embodiment in which the plasma step 11 is performed in a single power tool, the plasma step is comprised of a halogen flow rate of about 3 to 500 sccm, a process chamber pressure of from 1 mTorr to 3 Torr, a process chamber temperature between about −15° C. and 150° C., and a RF power from about 50 to 1000 Watts for a period of less than 60 seconds and preferably for 5 to 30 seconds.

Although the exact mechanism of the residue removal has not been determined, it is believed that a F radical or a Cl radical in the halogen containing plasma step reacts with SiO₂ residues to form a volatile silicon species. The volatile silicon species is swept away through an exit port in the process chamber. For instance, when CF₄ is employed as the halogen containing gas, then SiF₄ and CO₂ are formed as the volatile reaction products.

Referring to FIG. 5, after the oxide residues 8 are removed by the halogen containing plasma step 11, a third plasma step is performed in the etch tool and preferably in the same process chamber used for the oxygen ashing step and plasma step 11. The third plasma step is based on an etch chemistry such as Cl₂/O₂/He, HBr/O₂/He, or Cl₂/HBr/O₂/He and forms shallow trenches 9a, 9b, 9c in the substrate 1 below the openings 5, 6, 7, respectively. The active region 13 between the trenches 9a and 9b and the active region 14 between the trenches 9b and 9c will be used to form a transistor in subsequent steps.

One advantage of the first embodiment is that the halogen containing plasma step eliminates oxide residues caused by an oxygen ashing step so that no detrimental micro masking defects are formed during the third plasma step that generates shallow trenches. Thus, expensive rework steps to remove the micro mask defects are prevented. When the three plasma steps of the integrated process are carried out in the same process chamber, a high throughput of substrates is achieved.

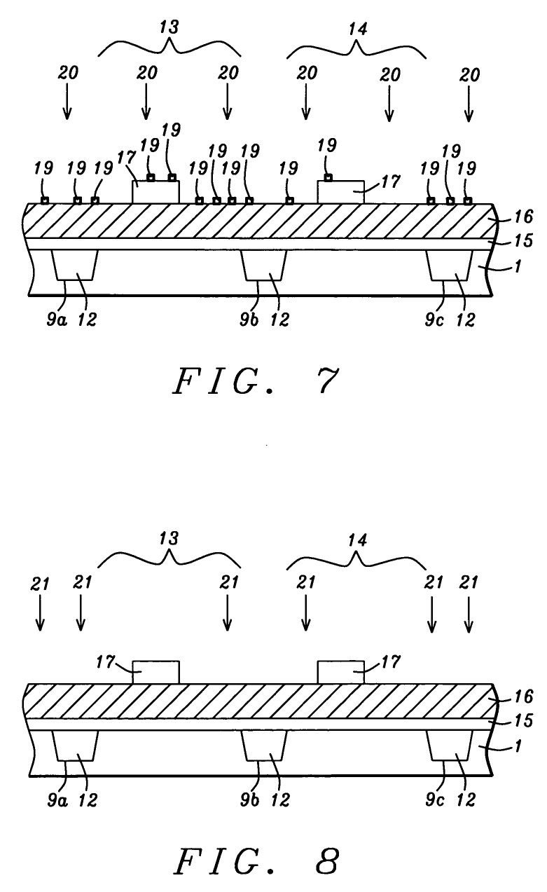

A second embodiment is set forth in FIGS. 6-9 and may be considered a continuation of the first embodiment since the process flow previously described for fabricating STI features may be further employed in a second integrated process flow to generate a partially formed transistor on an active region of the substrate. In another aspect, the second embodiment may be considered separately from the first embodiment in a process flow where STI features are fabricated by a method other than described in the first embodiment.

Referring to FIG. 6, a structure is shown that in an exemplary process flow of the second embodiment is derived from the structure pictured in FIG. 5 in which the active regions 13, 14 are formed between the shallow trenches 9a, 9b and 9b, 9c, respectively. The shallow trenches 9a, 9b, 9c are then filled with an insulating layer 12 such as SiO₂ or a low k dielectric layer by a CVD, PECVD, or a spin-on method. Optionally, an oxide liner (not shown) may be grown on the sidewalls and bottom of the shallow trenches 9a, 9b, 9c prior to deposition of the insulating layer 12. Typically, the insulating layer 12 is planarized by a chemical mechanical polish (CMP) process and hard mask 3 and pad oxide 2 are then removed by methods well known to those skilled in the art. For instance, a H₃PO₄ treatment may be used to remove a silicon nitride hard mask 3 while a dip in a dilute HF solution may be performed to remove a pad oxide layer 2. Although the insulating layer 12 is shown as coplanar with the top of substrate 1, the top of the insulating layer 12 may also be higher than the substrate.

A gate dielectric layer 15 comprised of SiO₂ or a high k dielectric material is formed on the substrate 1 and on the insulating layer 12 by conventional means. Next, a doped or undoped gate layer 16 that is preferably polysilicon or amorphous silicon is deposited on the gatedielectric layer 15. A hard mask layer 17 such as silicon nitride, silicon oxynitride, or silicon oxide is formed on the gate layer 16 by a CVD or PECVD technique. A hard mask layer 17 comprised of silicon oxynitride may serve as an anti-reflective coating (ARC) during a subsequent photoresist patterning step. Optionally, an organic ARC layer (not shown) is formed on the hard mask layer 17. A photoresist is coated on the hard mask layer 17 or on the ARC layer in the optional embodiment and is patterned by a conventional lithography method to generate a photoresist layer 18 that is preferably aligned over the center of active regions 13, 14. The photoresist layer 18 functions as a mask for the next step which is a plasma etch that anisotropically transfers the pattern in the photoresist layer through the hard mask layer 17.

Referring to FIG. 7, the photoresist layer 18 and optionally an organic ARC layer are removed by an oxygen ashing step in a process chamber of an etching tool as previously described in the first embodiment. Oxide residues 19 are formed because the oxygen radicals in the oxygen ashing step come in contact with silicon containing layers and thereby form SiO₂ residues that are non-volatile. The oxide residues 19 on the hard mask layer 17 and gate layer 16 must be removed before further processing to transfer the gate pattern into the gate layer 16 or micro masking defects will result.

A key feature of the second embodiment is a halogen containing plasma step 20 that effectively removes oxide residues 19 without damaging adjacent layers. The plasma step 20 is preferably based on one or more of the halogen containing gases CF₄, CH₂F₂, SF₆, NF₃, and Cl₂. Optionally, HBr or a fluorocarbon C_{X}F_{Y}H_{Z} may be used alone or with one or more of the aforementioned halogen containing gases. Preferably, the plasma step is carried out in the same etch tool that was used for the previous oxygen ashing step in order to enhance throughput. To decrease the amount of preventative maintenance needed to periodically clean the wall (not shown) of the O₂ ashing process chamber, the plasma step 20 is more preferably generated in the same process chamber that was used to strip the photoresist layer 18 in order to remove oxide residues from the O₂ ashing process chamber wall.

The plasma step 20 is comprised of a halogen flow rate of about 3 to 500 sccm, a chamber pressure of from 1 mTorr to 3 Torr, a chamber temperature between about −15° C. and 150° C., a HFRF power of from 100 to 3000 Watts and a LFRF power of about 10 to 1000 Watts for a period of less than 60 seconds and preferably for about 7 to 30 seconds. Optionally, an inert gas such as He, Ar, or N₂ may be flowed into the process chamber during the plasma step 20. In an alternative embodiment in which the plasma step 20 is performed in a single power tool, the plasma step is comprised of a halogen flow rate of about 3 to 500 sccm, a process chamber pressure of from 1 mTorr to 3 Torr, a process chamber temperature between about −15° C. and 150° C., and a RF power from about 50 to 1000 Watts for a period of less than 60 seconds and preferably for 7 to 30 seconds.

Referring to FIG. 8, after the oxide residues 19 are removed by the halogen containing plasma step 20, a third plasma step 21 is performed in the etch tool used for the oxygen ashing and plasma step 11 and preferably in the same process chamber used for the previous two steps. The third plasma step 21 is based on an etch chemistry such as Cl₂, HBr, and O₂ and transfers the pattern in the hard mask layer 17 through the gate layer 16.

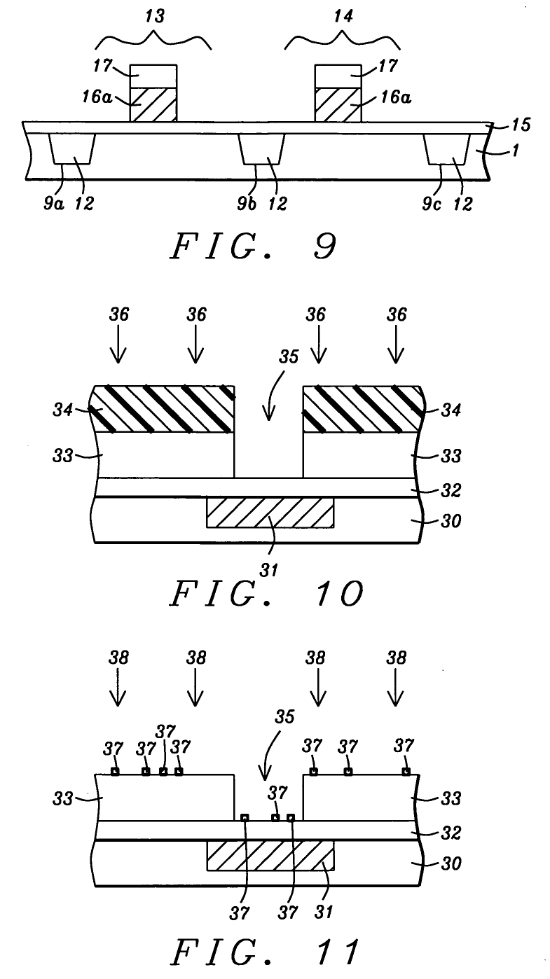

Referring to FIG. 9, gate electrodes 16a in active regions 13, 14 are formed as a result of the third plasma step 21. Note that hard mask layer 17 may be thinned somewhat because of the third plasma step 21. The structure shown in FIG. 9 is typically subjected to further processing to form transistors in the active regions 13, 14. However, the processes to form source/drain regions and spacers adjacent to the gate electrode are beyond the scope of this invention and are not included herein.

The advantage of the second embodiment is that gate electrodes are formed by an integrated plasma etch process involving an oxide residue removal method that avoids micro masking defects. The defect free substrate does not require expensive rework steps that are needed for prior art methods that produce photoresist ashing residues which are carried through a subsequent gate layer etch. Furthermore, when all three plasma steps of the integrated process flow are performed in the same process chamber, a high throughput is achieved.

A third embodiment is depicted in FIGS. 10-13 and involves an integrated process flow in which a first oxygen ashing step is used to remove a photoresist layer over a dielectric layer but generates oxide residues. A plasma step then removes oxide residues and an exposed etch stop layer at the bottom of an opening as part of a damascene scheme to fabricate an interconnect. An additional plasma step removes polymers that are generated by the previous plasma step.

Referring to FIG. 10, a substrate 30 is shown which is typically silicon but may optionally be comprised of silicon-on-insulator (SOI), silicon-germanium (SiGe), gallium-arsenide (GaAs) or other semiconductor materials used in the art. A conductive layer 31 is formed in substrate 30 by conventional means and has a top surface that is coplanar with the top surface of substrate 30. Optionally, a thin diffusion barrier layer (not shown) is formed along the sides and bottom of the conductive layer 31 to protect the conductive layer from corrosion and oxidation and to prevent ion migration from the conductive layer into adjacent regions of the substrate 30.

An etch stop layer 32 such as silicon nitride, silicon carbide, or silicon oxynitride is deposited on the substrate 30 and conductive layer 31 by a CVD or PECVD technique. Next, a dielectric layer 33 that may be an ILD or IMD layer is formed on the etch stop layer 32 by CVD or PECVD method. Dielectric layer 33 may be comprised of SiO₂, phosphosilicate glass (PSG), borophosphosilicate glass (BPSG), or a low k dielectric material such as fluorine doped SiO₂, carbon doped SiO₂, a silsesquioxane polymer, a poly(arylether), or benzocyclobutene. Optionally, a capping layer (not shown) such as silicon carbide, silicon nitride, or silicon oxynitride is formed on the dielectric layer 33.

A photoresist is coated on the dielectric layer 33 and is patterned to form a photoresist layer 34 having an opening 35 which may be a via, contact hole, or a trench. Alternatively, an organic ARC (not shown) is coated on the dielectric layer 33 or on the capping layer prior to coating the photoresist layer 34. The opening 35 is etch transferred through the dielectric layer 33 and stops on the etch stop layer 32. In the exemplary process flow of this embodiment, the opening 35 is a via, contact hole, or trench in a single damascene scheme. However, those skilled in the art will appreciate that this embodiment also anticipates a dual damascene scheme in which the opening 35 formed in the dielectric layer 33 consists of a trench formed above a via. In an alternative embodiment, the organic ARC exposed by the opening 35 is removed by an O₂ and Ar based plasma etch, for example, before the etch through the dielectric layer 33 which is typically based on a fluorocarbon gas chemistry.

The first step in the integrated process flow of the third embodiment is an oxygen ashing step 36 to remove the photoresist layer 34 and optionally an organic ARC layer. The oxygen ashing step 36 is carried out in a process chamber of an etch tool as previously described in the first embodiment.

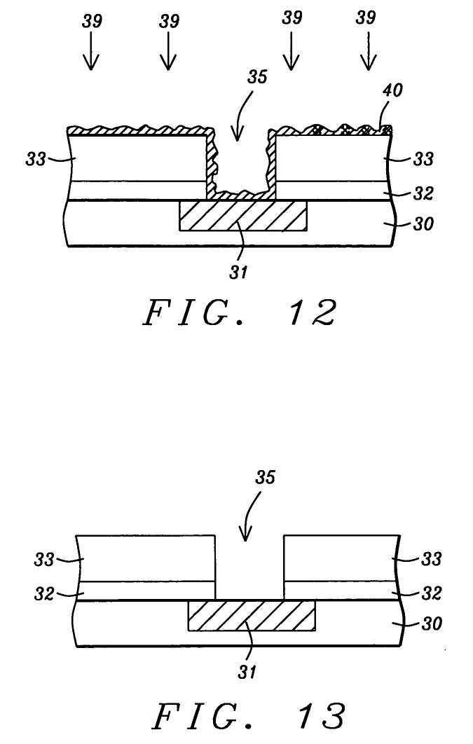

Referring to FIG. 11, oxide residues 37 are formed on the dielectric layer 33 and within the opening 35 as a result of the oxygen ashing step 36. A key feature of the integrated process flow of the third embodiment is a plasma step that removes the oxide residues 37 and the etch stop layer 32 exposed at the bottom of the opening 35. The plasma step is a halogen containing plasma stop 38 that is preferably based on one or more of the halogen containing gases CF₄, CH₂F₂, SF₆, NF₃, and Cl₂. Optionally, HBr or a fluorocarbon C_{X}F_{Y}H_{Z} may be used alone or with one or more of the aforementioned halogen containing gases. The plasma step 38 is preferably carried out in the same etch tool that was used for the oxygen ashing step 36 and more preferably is performed in the same process chamber that was used to strip the photoresist layer 34 in order to remove oxide residues that accumulate on the process chamber wall during an O₂ ashing step.

The plasma step 38 is comprised of a halogen flow rate of 3 to 500 sccm, a chamber pressure of from 1 mTorr to 3 Torr, a chamber temperature between −15° C. and 150° C., a HFRF power of 100 to 3000 Watts and a LFRF power of 10 to 1000 Watts for a period of <60 seconds and preferably for about 5 to 30 seconds. In an alternative embodiment in which the plasma step 38 is performed in a single power tool, the plasma step is comprised of a halogen flow rate of about 3 to 500 sccm, a process chamber pressure of from 1 mTorr to 3 Torr, a process chamber temperature between about −15° C. and 150° C., and a RF power from about 50 to 1000 Watts for a period of less than 60 seconds and preferably for 5 to 30 seconds.

Referring to FIG. 12, after the oxide residues 37 and the exposed portion of the etch stop layer 32 are removed by the halogen containing plasma step 38, an additional plasma step 39 in the integrated process flow of the third embodiment is performed in the same etch tool used for the oxygen ashing step 36 and the plasma stop 38 and preferably in the same process chamber as used for the previous two steps. The plasma step 39 is typically based on oxygen chemistry and removes polymer residues 40 in the opening 35 and on the surface of the dielectric layer 33 that were formed during the previous plasma step 38. Typically, the polymer residues 40 form a continuous covering on the dielectric layer 33 and within the opening 35.

Referring to FIG. 13, the damascene structure with opening 35 formed in the dielectric layer 33 and etch stop layer 32 is free of residue and is ready for further processing that usually includes depositing a diffusion barrier layer (not shown) on the side walls and bottom of the opening and depositing a metal layer (not shown) to fill the opening.

The advantage of the third embodiment is that oxide residues formed during a photoresist ashing step are cleanly removed so that micro masking defects which require expensive rework are avoided in a damascene scheme that produces a metal interconnect. Moreover, an exposed portion of an etch stop layer is removed at the same time as the oxide residues which avoids the use of an extra process stop just to remove the exposed etch stop layer. Furthermore, when the three steps of the integrated process flow are performed in the same process chamber, a high throughput is achieved.

While this invention has been particularly shown and described with reference to, the preferred embodiments thereof, it will be understood by those skilled in the art that various changes in form and details may be made without departing from the spirit and scope of this invention.

1. An integrated process flow involving a patterned photoresist layer on a substrate in an etching tool that has one or more process chambers, said patterned photoresist layer having an opening with a top and bottom that extends through at least one underlying layer in said substrate, comprising:
(a) performing an oxygen ashing step to remove said patterned photoresist layer;
(b) performing a halogen containing plasma step; and
(c) transferring said opening through an exposed layer at the bottom of said opening in said substrate.

2. The method of claim 1 wherein said etching tool is a split power etcher, a dual power etcher, a single power etch tool, a reactive ion etcher, or a conventional barrel, direct, or downstream type of ashing tool.

3. The method of claim 1 wherein steps (a) and (b) are performed in the same process chamber of said etching tool.

4. The method of claim 1 wherein steps (a), (b), and (c) are performed in the same process chamber of said etching tool.

5. The method of claim 1 wherein said halogen containing plasma step involves a plasma that is formed from one or more of CF₄, CH₂F₂, SF₆, NF₃, Cl₂ and C_{X}F_{Y}H_{Z} where x and y are integers and z is an integer or is 0.

6. The method of claim 5 wherein the halogen containing plasma step includes HBr in combination with one or more of CF₄, CH₂F₂, SF₆, NF₃, Cl₂ and C_{X}F_{Y}H_{Z} where x and y are integers and z is an integer or is 0.

7. The method of claim 1 wherein the halogen containing plasma step is comprised of a halogen containing gas flow rate of about 3 to 500 standard cubic centimeters per minute (sccm), a chamber pressure between about 1 mTorr and 3 Torr, a chamber temperature of about −15° C. to 150° C., a HFRF power or top RF power from about 100 to 3000 Watts, and a LFRF power or bias power of about 10 to 1000 Watts for a period of less than about 60 seconds.

8. The method of claim 1 wherein the etching tool is a single power tool and the halogen containing plasma step is comprised of a halogen containing gas flow rate of about 3 to 500 sccm, a chamber pressure between about 1 mTorr and 3 Torr, a chamber temperature of about −15° C. to 150° C., and a RF power from about 50 to 1000 Watts for a period of less than about 60 seconds.

9. The method of claim 1 wherein said opening exposes an underlying silicon layer and step (c) forms a shallow trench in said substrate.

10. The method of claim 1 wherein said opening exposes an underlying gate layer and step (c) forms a gate electrode.

11. An integrated process flow for removing oxide residues, comprising:
(a) providing a substrate upon which a stack comprised of an upper patterned photoresist layer, a middle masking layer, and a lower pad oxide layer is formed and positioning said substrate in a process chamber of an etching tool, said patterned photoresist layer having a trench opening that extends through the masking layer and pad oxide layer;
(b) performing an oxygen ashing step to remove the patterned photoresist layer, said oxygen ashing step generates oxide residues on said substrate; and
(c) performing a halogen containing plasma step to remove said oxide residues.

12. The method of claim 11 further comprised of a plasma etch after the halogen containing plasma step to transfer said trench opening into said substrate.

13. The method of claim 12 wherein said plasma etch step is performed in the same etch tool as the halogen containing plasma step.

14. The method of claim 11 wherein the masking layer is comprised of silicon nitride or polysilicon and the substrate is a silicon substrate.

15. The method of claim 11 wherein said halogen containing plasma step involves a plasma that is formed from one or more of CF₄, CH₂F₂, SF₆, NF₃, Cl₂ and C_{X}F_{Y}H_{Z} where x and y are integers and z is an integer or is 0.

16. The method of claim 11 wherein the halogen containing plasma treatment is comprised of a halogen containing gas flow rate of about 3 to 500 sccm, a chamber pressure between about 1 mTorr and 3 Torr, a chamber temperature of about −15° C. to 150° C., a HFRF power from about 100 to 3000 Watts, and a LFRF power of about 10 to 1000 Watts for a period of less than about 60 seconds.

17. The method of claim 11 wherein the etching tool is a single power tool and the halogen containing plasma step is comprised of a halogen containing gas flow rate of about 3 to 500 sccm, a chamber pressure between about 1 mTorr and 3 Torr, a chamber temperature of about −15° C. to 150° C., and a RF power from about 50 to 1000 Watts for a period of less than about 60 seconds.

18. The method of claim 11 wherein the stack further includes an organic ARC layer between the masking layer and the patterned photoresist layer and wherein the ARC layer is removed during the oxygen ashing step.

19. An integrated process flow for removing oxide residues, comprising:
(a) providing a substrate upon which a stack including a gate dielectric layer, a gate layer, a hard mask layer, and a photoresist layer are sequentially formed and positioning said substrate in a process chamber of an etching tool, said photoresist layer has a pattern comprised of openings that extend through the hard mask layer;
(b) performing an oxygen ashing step to remove the patterned photoresist layer, said oxygen ashing step generates oxide residues on said substrate; and
(c) performing a halogen containing plasma step to remove said oxide residues.

20. The method of claim 19 further comprised of a plasma etch after the halogen containing plasma step to transfer said pattern through the gate layer to form a gate electrode.

21. The method of claim 20 wherein said plasma etch step is performed in the same etch tool as the halogen containing plasma step.

22. The method of claim 19 wherein the gate dielectric layer is comprised of SiO₂ or a high k dielectric material.

23. The method of claim 19 wherein the gate layer is comprised of polysilicon or amorphous silicon.

24. The method of claim 19 wherein the hard mask is silicon nitride, silicon oxynitride, or silicon oxide.

25. The method of claim 19 wherein said halogen containing plasma step involves a plasma that is formed from one or more of CF₄, CH₂F₂, SF₆, NF₃, Cl₂ and C_{X}F_{Y}H_{Z} where x and y are integers and z is an integer or is 0.

26. The method of claim 19 wherein the halogen containing plasma step is comprised of a halogen containing gas flow rate of about 3 to 500 sccm, a chamber pressure between about 1 mTorr and 3 Torr, a chamber temperature of about −15° C. to 150° C., a HFRF power from about 100 to 3000 Watts, and a LFRF power of about 10 to 1000 Watts for a period of less than about 60 seconds.

27. The method of claim 19 wherein the etching tool is a single power tool and the halogen containing plasma step is comprised of a halogen containing gas flow rate of about 3 to 500 sccm, a chamber pressure between about 1 mTorr and 3 Torr, a chamber temperature of about −15° C. to 150° C., and a RF power from about 50 to 1000 Watts for a period of less than about 60 seconds.

28. The method of claim 19 wherein the stack further includes an organic ARC layer between the hard mask and the patterned photoresist layer and wherein the ARC layer is removed during the oxygen ashing step.

29. An integrated process flow for removing oxide residues, comprising:
(a) providing a substrate having a stack comprised of an upper patterned photoresist layer, a middle dielectric layer, and a lower etch stop layer formed thereon and positioning said substrate in a process chamber of an etching tool, said patterned photoresist layer having an opening formed therein which extends through said dielectric layer and exposes a portion of said etch stop layer;
(b) performing an oxygen ashing step to remove the patterned photoresist layer, said oxygen ashing step generates oxide residues on said substrate; and
(c) performing a halogen containing plasma step to remove said oxide residues and the exposed portion of said etch stop layer.

30. The method of claim 29 further comprised of a plasma process after the halogen containing plasma step to remove polymer residues formed during removal of the exposed etch stop layer.

31. The method of claim 30 wherein said plasma process is performed in the same etch tool as the halogen containing plasma step.

32. The method of claim 29 wherein the opening in the dielectric layer is a via, a contact hole, a trench, or a trench formed above a via.

33. The method of claim 29 wherein the stack is further comprised of a cap layer between the dielectric layer and the patterned photoresist layer.

34. The method of claim 29 wherein the stack is further comprised of an organic ARC layer between the dielectric layer and the patterned photoresist layer, said organic ARC is removed with the patterned photoresist during the oxygen ashing step.

35. The method of claim 29 wherein the etch stop layer is silicon nitride, silicon carbide, or silicon oxynitride.

36. The method of claim 29 wherein the dielectric layer is comprised of SiO₂, PSG, BPSG, or a low k dielectric material which is fluorine doped SiO₂, carbon doped SiO₂, a silsesquioxane polymer, a poly(arylether), or benzocyclobutene.

37. The method of claim 29 wherein said halogen containing plasma step involves a plasma that is formed from one or more of CF₄, CH₂F₂, SF₆, NF₃, Cl₂ and C_{X}F_{Y}H_{Z} where x and y are integers and z is an integer or is 0.

38. The method of claim 29 wherein the halogen containing plasma step is comprised of a halogen containing gas flow rate of about 3 to 500 sccm, a chamber pressure between about 1 mTorr and 3 Torr, a chamber temperature of about −15° C. to −150° C., a HFRF power from about 100 to 3000 Watts, and a LFRF power of about 10 to 1000 Watts for a period of less than about 60 seconds.

39. The method of claim 29 wherein the etching tool is a single power tool and the halogen containing plasma step is comprised of a halogen containing gas flow rate of about 3 to 500 sccm, a chamber pressure between about 1 mTorr and 3 Torr, a chamber temperature of about −15° C. to 150° C., and a RF power from about 50 to 1000 Watts for a period of less than about 60 seconds.
